(19) United States
(12) Patent Application Publication
(10) Pub. No.: US 2024/0032246 A1
(43) Pub. Date: Jan. 25, 2024

(54) MONITORING DEVICE AND COOLING SYSTEM

(71) Applicant: Fujitsu Limited, Kawasaki-shi (JP)

(72) Inventors: Yosuke ISAYAMA, Fukuoka (JP); Toshihiro SUZUKI, Kawasaki (JP); Atsushi KANAI, Kawasaki (JP)

(73) Assignee: Fujitsu Limited, Kawasaki-shi (JP)

(21) Appl. No.: 18/183,705

(22) Filed: Mar. 14, 2023

(30) Foreign Application Priority Data
Jul. 19, 2022 (JP) 2022-114763

(51) Int. Cl. H05K 7/20

(52) U.S. Cl. CPC H05K 7/20281; H05K 7/20254; H05K 7/20209

(57) ABSTRACT

A monitoring device includes a monitoring unit configured to monitor respective temperatures of an air-cooling target component and water-cooling target components measured by temperature sensors, respectively, and a determination unit configured to determine an abnormality in any one of cooling mechanisms provided in the water-cooling target components, respectively, based on a temperature relationship among the respective temperatures.

### CROSS-REFERENCE TO RELATED APPLICATION

This application is based upon and claims the benefit of priority of the prior Japanese Patent Application No. 2022-114763, filed on Jul. 19, 2022, the entire contents of which are incorporated herein by reference.

### FIELD

A certain aspect of embodiments described herein relates to a monitoring device and a cooling system.

### BACKGROUND

A cooling system using a coolant pump and a cooling system for a power conversion device mounted on an electric vehicle are known as disclosed in, for example, Japanese Patent Application Laid-Open Nos. 2016-015398 and 2013-084648. Note that the related art is also disclosed in Japanese Patent Application Laid-Open No. H07-146188.

### SUMMARY

In an optical transmission device (for example, a transponder or the like), an air-based cooling system is employed in order to dissipate heat of components mounted on a substrate. Some optical transmission devices employ a cooling system that uses both air cooling and water cooling.

In such cooling systems, the amount of coolant used for water cooling may decrease due to natural evaporation, liquid leakage, or the like. When the amount of coolant decreases, the cooling capacity of the cooling mechanism that uses the coolant to cool components decreases. Therefore, it is required to periodically determine whether the cooling capacity is maintained. When the cooling capacity is not maintained, for example, the cooling system may be replaced or the coolant may be replenished.

When the maintenance of the cooling capacity is determined, for example, it is assumed that a water amount sensor is provided in the cooling system, the amount of the coolant is measured by the water amount sensor, and the maintenance of the cooling capacity is determined. However, when the water amount sensor is provided in the cooling system, the size of the cooling system may increase. In addition, in this case, since the amount of the coolant required to maintain the cooling capacity varies depending on the temperature of the coolant and the environment surrounding the optical transmission device (for example, temperature, humidity, atmospheric pressure, and the like), it is difficult to uniquely set the threshold value for determining the maintenance of the cooling capacity for each environment. It is also conceivable to set a plurality of threshold values, but in this case, various conditions for determining the maintenance of the cooling capacity are required to be separately examined, arising another problem that the setting becomes complicated.

Even when a decrease in the amount of coolant above a threshold value is observed, there may still be a sufficient amount of coolant remaining in the cooling system to cool the components. In such a case, it is not an appropriate time for replacement of the cooling system or replenishment of the coolant, and thus it is desirable to accurately specify the timing of replacement or replenishment.

According to an aspect of the embodiments, there is provided a monitoring device including: a monitoring unit configured to monitor respective temperatures of an air-cooling target component and water-cooling target components measured by temperature sensors, respectively; and a determination unit configured to determine an abnormality in any one of cooling mechanisms provided in the water-cooling target components, respectively, based on a temperature relationship among the respective temperatures.

The object and advantages of the invention will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIG. 1 is an example of a plan view of a cooling system.

FIG. 2 is a schematic diagram illustrating details of the cooling system.

FIG. 3A is an example of a plan view of a cooling mechanism, and

FIG. 3B is an example of a front view of the cooling mechanism.

FIG. 4A illustrates a functional configuration of a monitoring device, and

FIG. 4B illustrates a hardware configuration of the monitoring device.

FIG. 5 is a flowchart illustrating the operation of the monitoring device.

FIG. 6A is a graph (part 1) illustrating a temperature variation of an air-cooling target component, and FIG. 6B is a graph (part 1) illustrating a temperature variation of a water-cooling target component.

FIG. 7A is a graph (part 2) illustrating a temperature variation of the air-cooling target component, and FIG. 7B is a graph (part 2) illustrating a temperature variation of the water-cooling target component.

FIG. 8A is a graph (part 3) illustrating a temperature variation of the air-cooling target component, and FIG. 8B is a graph (part 3) illustrating a temperature variation of the water-cooling target component.

FIG. 9 illustrates determination based on the rotation speed of rotations of an air-cooling fan and relationships among respective temperatures of air-cooling target components and respective temperatures of water-cooling target components.

### DESCRIPTION OF EMBODIMENTS

Hereinafter, embodiments of the present disclosure will be described with reference to the drawings.

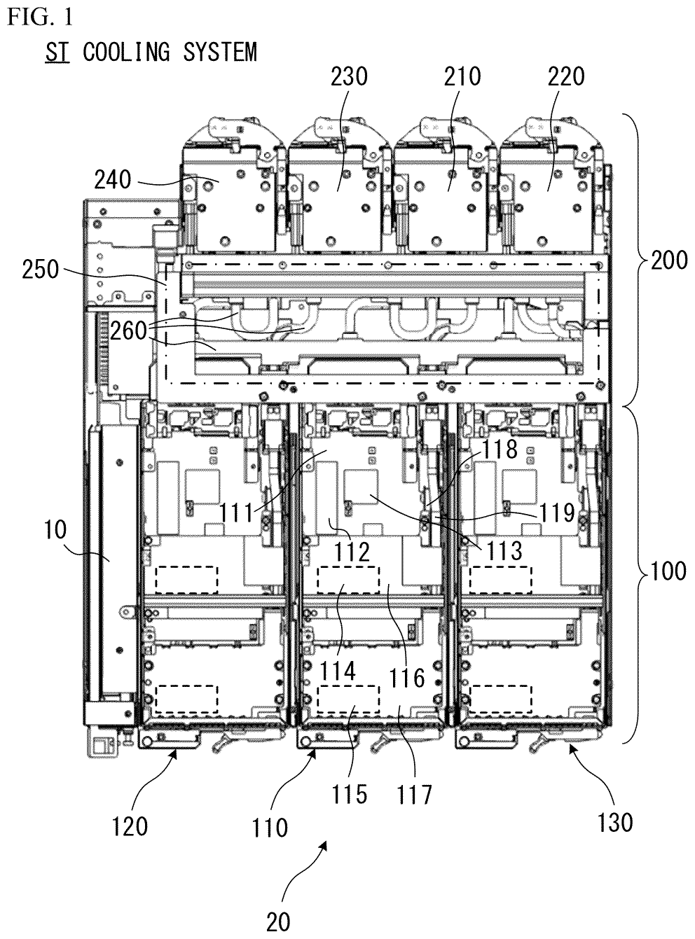

As illustrated in FIG. 1, a cooling system ST includes a monitoring device 10 and a monitored device 20. The monitoring device 10 monitors the monitored device 20. The cooling system ST may be an optical transmission device (specifically, a transponder), or may be a reconfigurable optical add/drop multiplexer (ROADM).

The monitored device 20 includes a cooling target device 100 and a cooling device 200. The cooling target device 100 includes a plurality of optical processing devices 110, 120, and 130. The optical processing device 110 executes, for example, a process of converting an electric signal into an optical signal and a process of converting an optical signal into an electric signal. Since the optical processing devices 120 and 130 execute the same processing as the optical processing device 110, a detailed description thereof will be omitted. Each of the optical processing devices 110, 120, and 130 can be individually removed from the cooling device 200, and can be individually attached to the cooling device 200. That is, the optical processing devices 110, 120, and 130 are attachable to and detachable from the cooling device 200. Therefore, for example, when the optical processing device 130 malfunctions while the optical processing devices 110 and 120 are not malfunctioning, the optical processing device 130 can be independently replaced.

All the optical processing devices 110, 120, and 130 have the same configuration. Therefore, the optical processing device 110 will be described as an example. The optical processing device 110 includes a substrate 111, a plurality of air-cooling target components 112 and 113, a plurality of water-cooling target components 114 and 115, and cooling mechanisms 116 and 117. The water-cooling target components 114 and 115 are hidden by the cooling mechanisms 116 and 117, respectively. In the present embodiment, the optical processing device 110 includes the air-cooling target components 112 and 113, but the optical processing device 110 may include either one of the air-cooling target components 112 and 113. Each of the air-cooling target components 112 and 113 and the water-cooling target components 114 and 115 may be a large-scale integration (LSI) or a digital signal processor (DSP). Each of the air-cooling target components 112 and 113 and the water-cooling target components 114 and 115 may be a field programmable gate array (FPGA) or an application specific integrated circuit (ASIC).

The air-cooling target components 112 and 113 and the water-cooling target components 114 and 115 are all mounted on the substrate 111. The cooling mechanism 116 is bonded to the top surface of the water-cooling target component 114. The cooling mechanism 117 is bonded to the top surface of the water-cooling target component 115. As described above, the cooling mechanisms 116 and 117 are provided in close contact with the top surfaces of the water-cooling target components 114 and 115, respectively. As will be described in detail later, since a coolant flows inside the cooling mechanisms 116 and 117, the cooling mechanisms 116 and 117 release heat generated from the water-cooling target components 114 and 115 by heat exchange with the coolant. The water-cooling target components 114 and 115 are cooled by heat dissipation of the water-cooling target components 114 and 115 caused by the coolant. Since the water-cooling target components 114 and 115 generate a larger amount of heat than the air-cooling target components 112 and 113, the cooling mechanisms 116 and 117 having high cooling capacity are employed.

The cooling device 200 includes a plurality of cooling units 210, 220, 230, and 240, a radiator 250, a coolant path 260, and the like. Since the radiator 250 has been removed from the cooling device 200, the coolant path 260 is illustrated exposed. In the present embodiment, the cooling device 200 includes four cooling units 210, 220, 230, and 240, but the number of cooling units is not particularly limited. The cooling units 210, 220, 230, and 240 can be detached from the cooling device 200 and attached to the cooling device 200. Thus, the cooling units 210, 220, 230, and 240 are attachable to and detachable from the cooling device 200.

The coolant path 260 is connected to the cooling units 210, 220, 230, and 240. A coolant flows through the coolant path 260. The coolant flowing through the coolant path 260 flows into each of the cooling units 210, 220, 230, and 240. As will be described in detail later, each of the cooling units 210, 220, 230, and 240 includes a water-cooling pump that pumps the coolant. The coolant pumped by the water-cooling pump flows through the coolant path 260 and flows into the cooling mechanisms 116 and 117 through a coolant path 118, which is connected to the coolant path 260, of the optical processing device 110.

As described above, the coolant flowing through the cooling mechanisms 116 and 117 absorbs the heat generated from the water-cooling target components 114 and 115 and is discharged to a coolant path 119 of the optical processing device 110. The coolant path 119 is connected to the coolant path 260. As a result, the post-heat-absorption coolant, which is the coolant that has absorbed heat, flows from the coolant path 119 into the coolant path 260, and the heat thereof is dissipated by the radiator 250 provided on the coolant path 260. Therefore, the cooled coolant, which is the coolant cooled by heat dissipation, flows into the cooling units 210, 220, 230, and 240. When the cooled coolant flows into the cooling units 210, 220, 230, and 240, the cooling units 210, 220, 230, and 240 pump the cooled coolant again. As described above, the coolant circulates through the coolant paths 118, 119, and 260 and transfers the heat of the water-cooling target components 114 and 115 while changing its state to the post-heat-absorption coolant or the cooled coolant. Thus, the water-cooling target components 114 and 115 are cooled.

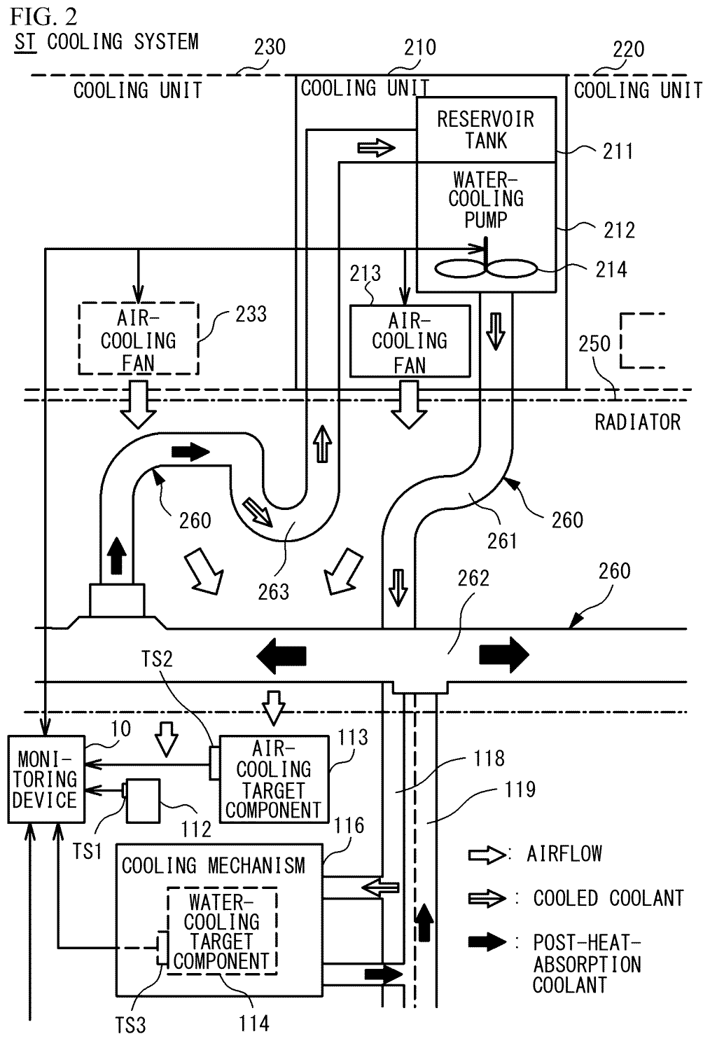

The cooling system ST will be described in more detail with reference to FIG. 2.

The cooling unit 210 includes a reservoir tank 211, a water-cooling pump 212, and an air-cooling fan 213. The reservoir tank 211 may not be necessarily provided in the cooling unit 210. The water-cooling pump 212 includes a pumping fan 214 such as a screw. The cooling units 220 and 230 and the cooling unit 240 (see FIG. 1) basically have the same configuration as the cooling unit 210. Therefore, the cooling unit 210 will be basically described below as an example, and a detailed description of the cooling units 220, 230, and 240 will be omitted.

The reservoir tank 211 stores the cooled coolant flowing into the cooling unit 210. The water-cooling pump 212 pumps the cooled coolant stored in the reservoir tank 211 by rotation of the pumping fan 214, and causes the cooled coolant to flow out to a first path 261 included in the coolant path 260. The first path 261 is connected to the coolant path 118. Therefore, the cooled coolant flowing out to the first path 261 flows into the coolant path 118. Since the coolant path 118 is present between the coolant path 119 and the top surface of the substrate 111, the coolant path 118 is partially hidden by the coolant path 119. A portion of the cooled coolant flowing into the coolant path 118 flows into the cooling mechanism 116. The remaining portion of the cooled coolant flows into the cooling mechanism 117 (see FIG. 1).

The post-heat-absorption coolant that has passed through the inside of the cooling mechanism 116 flows into the coolant path 119. The post-heat-absorption coolant flowing into the coolant path 119 merges with the post-heat-absorption coolant that has passed through the inside of the cooling mechanism 117 and flown out to the coolant path 119. Since the coolant path 119 is connected to a second path 262 of the coolant path 260, the post-heat-absorption coolant flows into the second path 262. A portion of the post-heat-absorption coolant that has flown into the second path 262 flows into a third path 263 of the coolant path 260.

The post-heat-absorption coolant that has flown into the third path 263 is cooled by the radiator 250 and becomes a cooled coolant. Airflow generated by rotation of the air-cooling fan 213 passes through the radiator 250. The airflow passes through the gaps of the radiator 250 and under the radiator 250. When the radiator 250 is cooled by the airflow, the post-heat-absorption coolant becomes a cooled coolant. The cooled coolant that has changed from the post-heat-absorption coolant flows into the cooling unit 210. As described above, the coolant circulates while changing its state to either the post-heat-absorption coolant or the cooled coolant.

The airflow that has passed through the radiator 250 reaches the air-cooling target components 112 and 113. Therefore, the air-cooling target components 112 and 113 are cooled by the airflow. On the other hand, the water-cooling target components 114 and 115 are disposed at positions where the air-cooling target components 112 and 113 are less likely to be exposed to the airflow. For this reason, cooling (specifically, water cooling or liquid cooling) using a coolant and the cooling mechanisms 116 and 117 is adopted for the water-cooling target components 114 and 115 in consideration of the amount of heat generated by the water-cooling target components 114 and 115.

A temperature sensor TS1 is attached to the air-cooling target component 112. A temperature sensor TS2 is attached to the air-cooling target component 113. A temperature sensor TS3 is attached to the water-cooling target component 114. Although not illustrated, a temperature sensor is also attached to the water-cooling target component 115 (see FIG. 1). The temperature sensor TS1 measures the temperature of the air-cooling target component 112 and reports the measured temperature to the monitoring device 10. The temperature sensor TS2 measures the temperature of the air-cooling target component 113 and reports the measured temperature to the monitoring device 10. The temperature sensor TS3 measures the temperature of the water-cooling target component 114 and reports the measured temperature to the monitoring device 10. The temperature sensor attached to the water-cooling target component 115 measures the temperature of the water-cooling target component 115 and reports the measured temperature to the monitoring device 10.

The monitoring device 10 detects respective temperatures of the air-cooling target components 112 and 113 and the water-cooling target components 114 and 115 measured by the temperature sensors TS1, TS2, TS3, and the like, and checks a temperature rise of each temperature. The monitoring device 10 determines the abnormality of any one of the cooling mechanisms 116 and 117, a decrease in the amount of the coolant, or the like based on the temperature relationships among the detected temperatures. Based on the determination result, the monitoring device 10 controls the rotation speed of each of the air-cooling fans 213 and 234 or the like, or controls the rotation speed of the pumping fan 214 of the water-cooling pump 212.

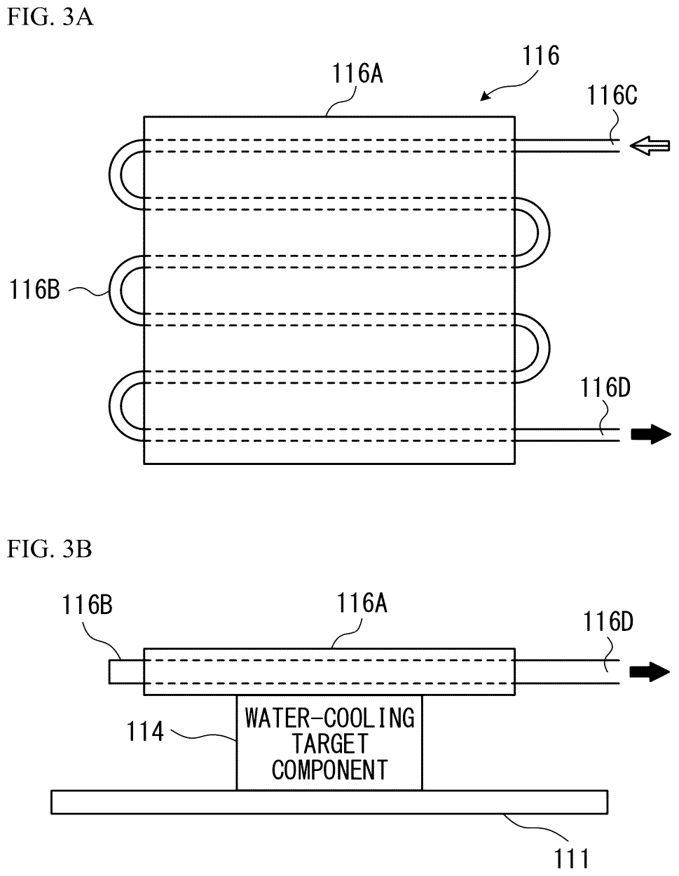

Next, the cooling mechanism 116 will be described in detail with reference to FIG. 3A and FIG. 3B. Since the cooling mechanism 117 basically has the same configuration as the cooling mechanism 116, a detailed description thereof will be omitted.

As illustrated in FIG. 3A and FIG. 3B, the cooling mechanism 116 includes a plate 116A made of metal containing aluminum and a serpentine tube 116B. The cooling mechanism 116 may be, for example, a cooling plate or a chill plate. The serpentine tube 116B is disposed inside the plate 116A. The serpentine tube 116B passes through the interior of the plate 116A. The serpentine tube 116B includes an inlet 116C and an outlet 116D. The inlet 116C is connected to the coolant path 118 (see FIG. 2). Therefore, the cooled coolant flowing through the coolant path 118 flows from the inlet 116C into the serpentine pipe 116B.

As illustrated in FIG. 3B, the top surface of the water-cooling target component 114 mounted on the substrate 111 and the bottom surface of the plate 116A are disposed in close contact with each other through, for example, an adhesive. Therefore, heat (to be specific, hot heat) generated in the water-cooling target component 114 is transferred to the cooled coolant flowing through the serpentine pipe 116B, through the plate 116A. On the other hand, heat (to be specific, cold heat) of the cooled coolant is transferred to the water-cooling target component 114 through the plate 116A. In this manner, heat exchange is performed between the water-cooling target component 114 and the cooled coolant. As a result, the water-cooling target component 114 is cooled, while the cooled coolant changes into the post-heat-absorption coolant in the process of passing through the inside of the serpentine tube 116B. The post-heat-absorption coolant is guided to the outlet 116D. The outlet 116D is connected to the coolant path 119 (see FIG. 2). Therefore, the post-heat-absorption coolant flows out from the outlet 116D, flows into the coolant path 119, and flows toward the second path 262 of the coolant path 260.

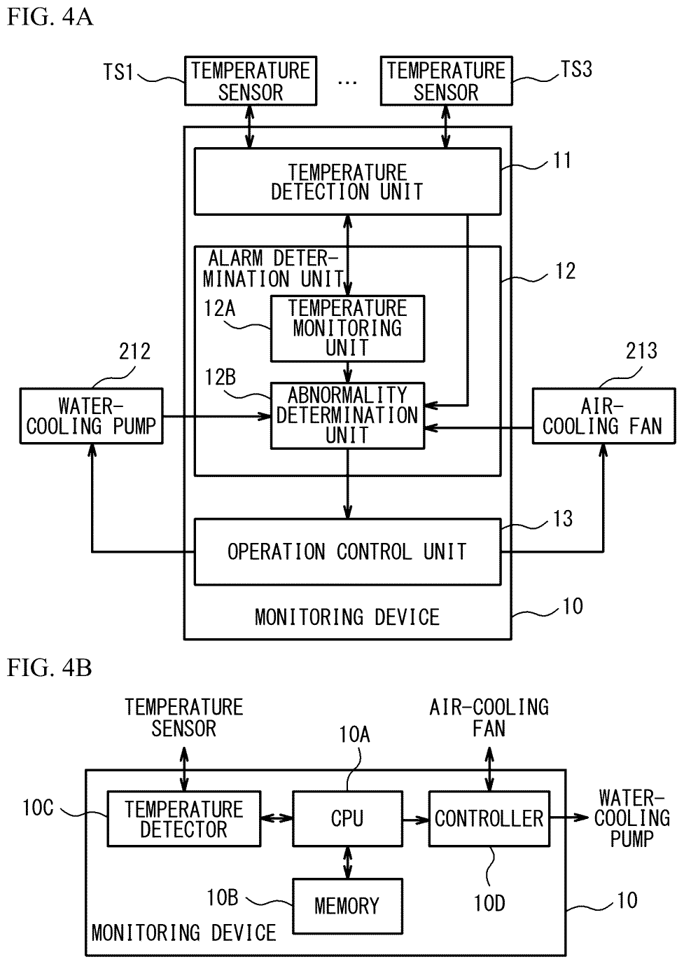

Next, the monitoring device 10 will be described in detail with reference to FIG. 4A and FIG. 4B.

As illustrated in FIG. 4A, the monitoring device 10 includes a temperature detection unit 11, an alarm determination unit 12, and an operation control unit 13. The alarm determination unit 12 includes a temperature monitoring unit 12A and an abnormality determination unit 12B. The temperature monitoring unit 12A is an example of a monitoring unit. The abnormality determination unit 12B is an example of a determination unit.

As illustrated in FIG. 4B, the alarm determination unit 12 can be implemented by a central processing unit (CPU) 10A and a memory 10B storing a program according to a flowchart described later. The memory 10B includes, for example, a random access memory (RAM) and a read only memory (ROM). When the CPU 10A reads and executes the program, the CPU 10A implements the temperature monitoring unit 12A and the abnormality determination unit 12B. The temperature detection unit 11 can be implemented by a temperature detector 10C including a hardware circuit. The temperature detector 10C may be provided not in the monitoring device 10 but in the substrate 111. The operation control unit 13 can be implemented by a controller 10D including a hardware circuit. The controller 10D may be provided not in the monitoring device 10 but in the substrate 111.

The temperature detection unit 11 detects respective temperatures reported from the temperature sensors TS1, TS2, TS3 and the like, and checks the temperature rise of each temperature. The temperature monitoring unit 12A acquires each temperature detected by the temperature detection unit 11 and monitors respective temperatures of the air-cooling target components 112 and 113 and the water-cooling target components 114 and 115. The abnormality determination unit 12B determines an abnormality in either one of the cooling mechanisms 116 and 117 or a decrease in the amount of the coolant, based on the temperature relationship among the temperatures of the air-cooling target components 112 and 113 and the water-cooling target components 114 and 115. To be specific, the abnormality determination unit 12B determines an abnormality such as a decrease in cooling capacity due to peeling of the cooling mechanisms 116 and 117 from the water-cooling target components 114 and 115, a decrease in the amount of the coolant supplied to the cooling mechanisms 116 and 117, or the like. Based on the determination result, the abnormality determination unit 12B generates a first control instruction for controlling the air-cooling fan 213 and a second control instruction for controlling the water-cooling pump 212, and outputs the first control instruction and the second control instruction to the operation control unit 13.

The operation control unit 13 controls the operation of the air-cooling fan 213 based on the first control instruction, and controls the operation of the water-cooling pump 212 (specifically, the operation of the pumping fan 214) based on the second control instruction. For example, the operation control unit 13 increases the rotation speed of the air-cooling fan 213. On the other hand, even when the rotation speed of the pumping fan 214 is increased, the cooling capacity hardly changes and is constant because the coolant is cooled by the radiator 250. Therefore, the operation control unit 13 does not increase the rotation speed of the pumping fan 214 but controls the rotation speed to a rotation speed at which a constant cooling capacity is maintained. Each of the air-cooling fan 213 and the water-cooling pump 212 periodically report their own states (for example, the current rotation speed) to the abnormality determination unit 12B.

As described above, the alarm determination unit 12 determines an abnormality of the cooling mechanism 116 or 117, a decrease in the amount of coolant, or the like. When the alarm determination unit 12 determines that an abnormality of the cooling mechanism 116 or 117 or a decrease in the amount of the coolant has occurred, the alarm determination unit 12 may notify, for example, an operation system (not illustrated) connected to the monitoring device 10 of an alarm corresponding to the type of occurrence.

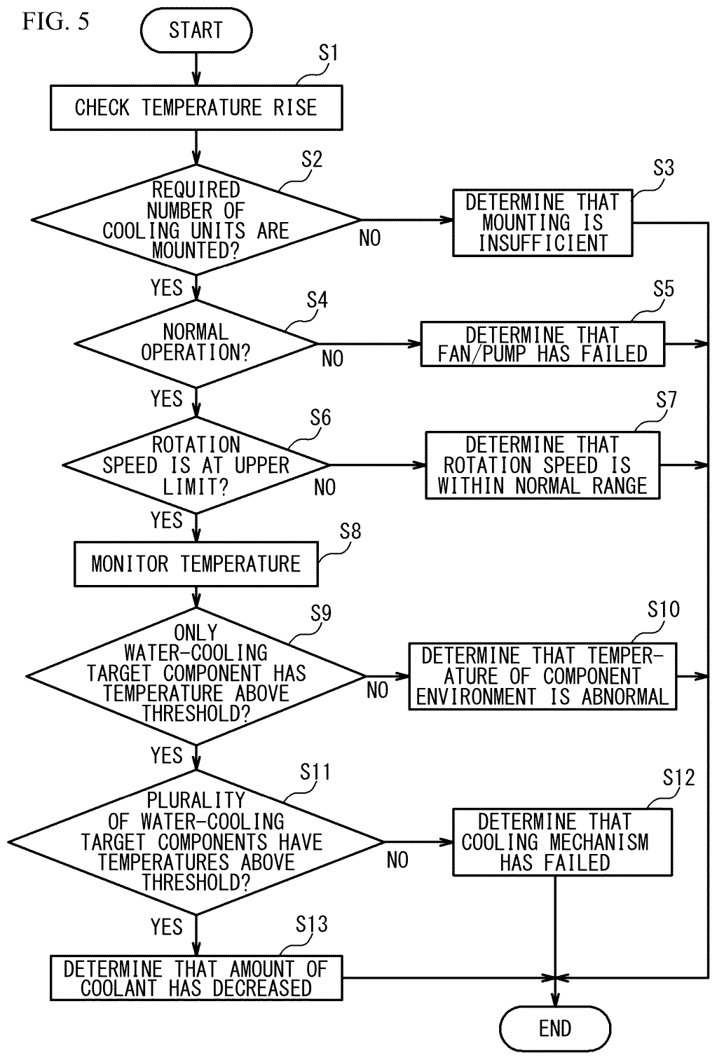

Next, the operation of the monitoring device 10 will be described with reference to FIG. 5 to FIG. 8B.

First, as illustrated in FIG. 5, the temperature detection unit 11 checks temperature rises of the air-cooling target components 112 and 113 and the water-cooling target components 114 and 115 (step S1). More specifically, when electric power is supplied to the cooling system ST and the cooling system ST operates, each of the monitoring device 10 and the monitored device 20 starts processing. For example, when the optical processing device 110 of the monitored device 20 starts processing, the air-cooling target components 112 and 113 and the water-cooling target components 114 and 115 generate heat. As a result, the respective temperatures of the air-cooling target components 112 and 113 and the water-cooling target components 114 and 115 rise. When the cooling device 200 of the monitored device 20 starts processing, the air-cooling fan 213 of the cooling unit 210 rotates at a rotation speed of 1000 revolutions per second, which is the initial value. When the cooling device 200 starts processing, the pumping fan 214 of the water-cooling pump 212 rotates at a predetermined rotation speed to pump the coolant. Thus, the air-cooling target components 112 and 113 and the water-cooling target components 114 and 115 are cooled.

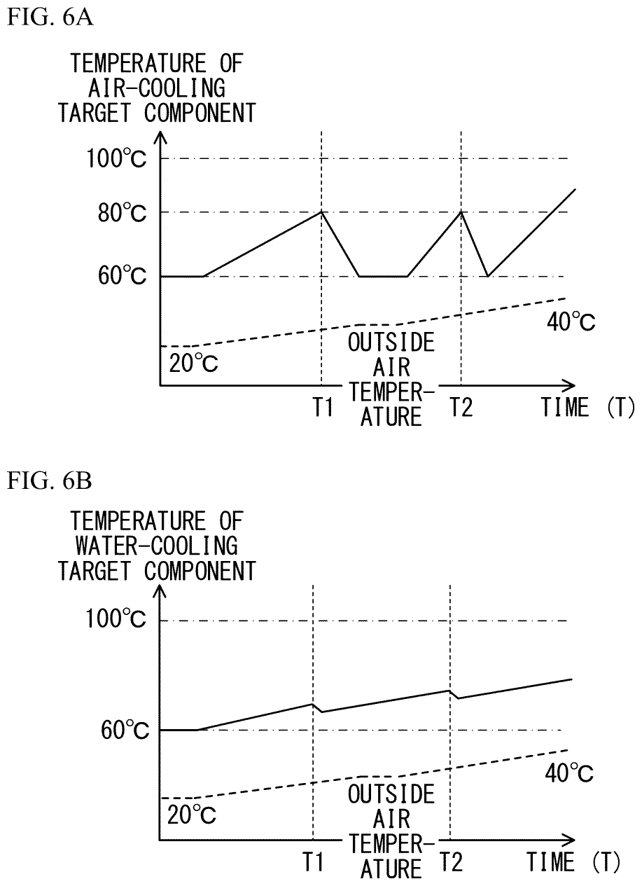

As illustrated in FIG. 6A, for example, when the temperature of the outside air (the outside air temperature) above the substrate 111 is 20° C., the temperature of each of the air-cooling target components 112 and 113 is maintained at 60° C. by the heat generation of the air-cooling target components 112 and 113 and the cooling by the air-cooling fans 213 and 233. As illustrated in FIG. 6B, when the outside air temperature above the substrate 111 is 20° C., the temperature of each of the water-cooling target components 114 and 115 is maintained at 60° C. by the heat generation of the water-cooling target components 114 and 115 and the cooling by the cooling mechanisms 116 and 117.

When the temperature detection unit 11 checks the temperature rise of each component, the abnormality determination unit 12B determines whether the required number of the cooling units 210, . . . , 240 are mounted (step S2), as illustrated in FIG. 5. In the present embodiment, when the four cooling units 210, . . . , 240 are mounted on the cooling device 200, the abnormality determination unit 12B determines that the required number of the cooling units 210, . . . , 240 are mounted (step S2: YES). For example, when any one of the cooling units 210, . . . , 240 is missing in the cooling device 200, the abnormality determination unit 12B determines that the required number of the cooling units 210, . . . , 240 are not mounted (step S2: NO). In this case, the abnormality determination unit 12B determines that the mounting is insufficient (step S3), issues an alarm as necessary, and ends the process. The abnormality determination unit 12B can determine whether the required number of the cooling units 210, . . . , 240 are mounted on the basis of a predetermined electric signal that conducts each time the cooling units 210, . . . , 240 are attached to the cooling device 200 one by one.

When the required number of the cooling units 210, . . . , 240 are mounted, the abnormality determination unit 12B determines whether the air-cooling fan 213 and the water-cooling pump 212 are operating normally (step S4). For example, when there is no periodic notification from one or both of the air-cooling fan 213 and the water-cooling pump 212, the abnormality determination unit 12B determines that one or both of the air-cooling fan 213 and the water-cooling pump 212 from which no notification is received are not operating normally (step S4: NO). In this case, the abnormality determination unit 12B determines that the air-cooling fan 213 or the water-cooling pump 212 has failed (step S5), issues an alarm as necessary, and ends the process. On the other hand, when there are periodic notifications from both the air-cooling fan 213 and the water-cooling pump 212, the abnormality determination unit 12B determines that the air-cooling fan 213 and the water-cooling pump 212 are operating normally (step S4: YES).

In this case, the abnormality determination unit 12B determines whether the rotation speed of the air-cooling fan 213 is at the upper limit (step S6). For example, as illustrated in FIG. 6A, as the outside air temperature rises, the temperatures of the air-cooling target components 112 and 113 also rise in accordance with the rise in the outside air temperature. When the temperatures of the air-cooling target components 112 and 113 exceed 80° C., which is a first threshold value for changing the rotation speed of the air-cooling fan 213, at time T1, the abnormality determination unit 12B changes the rotation speed of the air-cooling fan 213 from the initial value to 1500 revolutions per second through the operation control unit 13. As a result, the air-cooling target components 112 and 113 are cooled by the airflow, so that the temperatures of the air-cooling target components 112 and 113 decrease and are maintained at 60° C. for a certain period of time.

As illustrated in FIG. 6B, as the outside air temperature rises, the temperatures of the water-cooling target components 114 and 115 also rise in accordance with the rise in the outside air temperature. Here, as described above, when the rotation speed of the air-cooling fan 213 is changed to 1500 revolutions per second at time T1, the radiator 250 is cooled by the airflow, so that the temperature of the coolant decreases. As a result, as illustrated in FIG. 6B, the temperatures of the water-cooling target components 114 and 115 also decrease only for a short time. The slope at which the temperatures of the water-cooling target components 114 and 115 decrease is smaller than the slope at which the temperatures of the air-cooling target components 112 and 113 decrease.

Referring back to FIG. 6A, when the outside air temperature further rises, the temperatures of the air-cooling target components 112 and 113 rise again from 60° C. in accordance with the further rise in the outside air temperature. When the temperatures of the air-cooling target components 112 and 113 again exceed 80° C., which is the first threshold value for changing the rotation speed of the air-cooling fan 213, at time T2, the abnormality determination unit 12B changes the rotation speed of the air-cooling fan 213 from 1500 revolutions per second to the upper limit of the rotation speed (for example, 2000 revolutions per second or 2500 revolutions per second) through the operation control unit 13. As a result, the air-cooling target components 112 and 113 are cooled by the airflow, and the temperatures of the air-cooling target components 112 and 113 decrease and reach 60° C. However, after the rotation speed of the air-cooling fan 213 reaches the upper limit, the rotation speed is at the upper limit, and thus the abnormality determination unit 12B cannot increase the rotation speed of the air-cooling fan 213.

As a result, after time T2, the temperatures of the air-cooling target components 112 and 113 may exceed 100° C., which is the guaranteed limit temperature of the component. For the same reason, as illustrated in FIG. 6B, after time T2, the temperatures of the water-cooling target components 114 and 115 may also exceed 100° C., which is the guaranteed limit temperature of the component. As described above, the abnormality determination unit 12B determines whether the rotation speed of the air-cooling fan 213 has reached the upper limit based on the notification indicating the state of the air-cooling fan 213, output from the air-cooling fan 213. When the rotation speed of the air-cooling fan 213 has not reached the upper limit (step S6: NO), it is determined that the rotation speed of the air-cooling fan 213 is within the normal range (step S7), and the process is ended.

When the rotation speed of the air-cooling fan 213 is within the normal range (i.e., when the rotation speed has not reached the upper limit), the abnormality determination unit 12B determines that the temperatures of the air-cooling target components 112 and 113 and the temperatures of the water-cooling target components 114 and 115 are normal temperatures. In this case, the abnormality determination unit 12B determines that the cooling system is operating normally. To be specific, the abnormality determination unit 12B determines that there is no failure such as peeling of the cooling mechanisms 116 and 117, a decrease in the amount of the coolant, or blockage of the ventilation hole (or vent hole) provided in the rack (or housing) accommodating the cooling system ST.

On the other hand, when the rotation speed of the air-cooling fan 213 is at the upper limit (step S6: YES), the temperature monitoring unit 12A starts to acquire each temperature detected by the temperature detection unit 11 and monitors each temperature (step S8). More specifically, the temperature monitoring unit 12A monitors each temperature, and determines whether each temperature is higher than a second threshold temperature for determining an abnormality of the component. The second threshold temperature (e.g., 85° C. or 90° C.) is higher than the first threshold temperature and lower than the guaranteed limit temperature of the component.

The temperature monitoring unit 12A determines whether the component of which the temperature is higher than the second threshold temperature is only the water-cooling target components 114 and 115 (step S9). For example, when the components of which the temperatures are higher than the second threshold temperature include not only the water-cooling target components 114 and 115 but also the air-cooling target components 112 and 113, the temperature monitoring unit 12A determines that the components of which the temperatures are higher than the second threshold temperature are not only the water-cooling target components 114 and 115 (step S9: NO). In this case, the abnormality determination unit 12B determines that the temperature of the component environment is abnormal (step S10), issues an alarm as necessary, and ends the process.

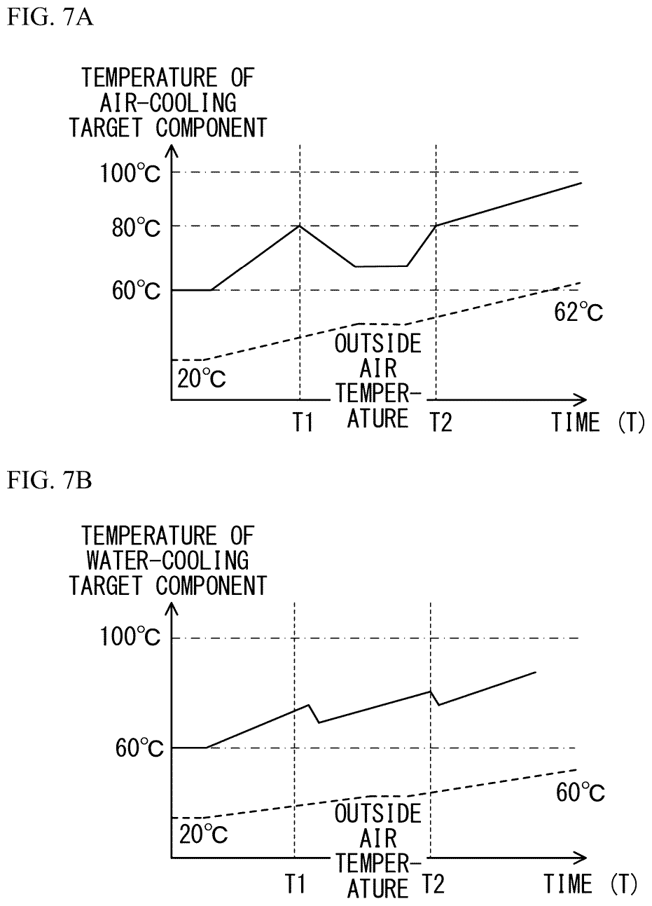

For example, as illustrated in FIG. 7A, when the ventilation hole of the rack accommodating the cooling system ST is blocked by dust, paper pieces, or the like, the outside air temperature above the substrate 111 rises from 20° C. to 60° C. or higher. As the outside air temperature rises, the temperatures of the air-cooling target components 112 and 113 also rise to the second threshold temperature or higher. In this case, the abnormality determination unit 12B determines that the temperatures of the air-cooling target components 112 and 113 are abnormal temperatures. In addition, as illustrated in FIG. 7B, the temperatures of the water-cooling target components 114 and 115 also rise to the second threshold temperature or higher in accordance with the rise in the outside air temperature. As described above, when the temperatures of the air-cooling target components 112 and 113 and the water-cooling target components 114 and 115 rise and are all abnormal temperatures, the abnormality determination unit 12B can determine that the cause of the abnormal temperatures is not insufficient cooling capacity due to a decrease in the amount of the coolant based on the temperature relationship among the temperatures. That is, in the case of such a temperature change, the abnormality determination unit 12B determines that there is an environmental abnormality in the environment surrounding the components.

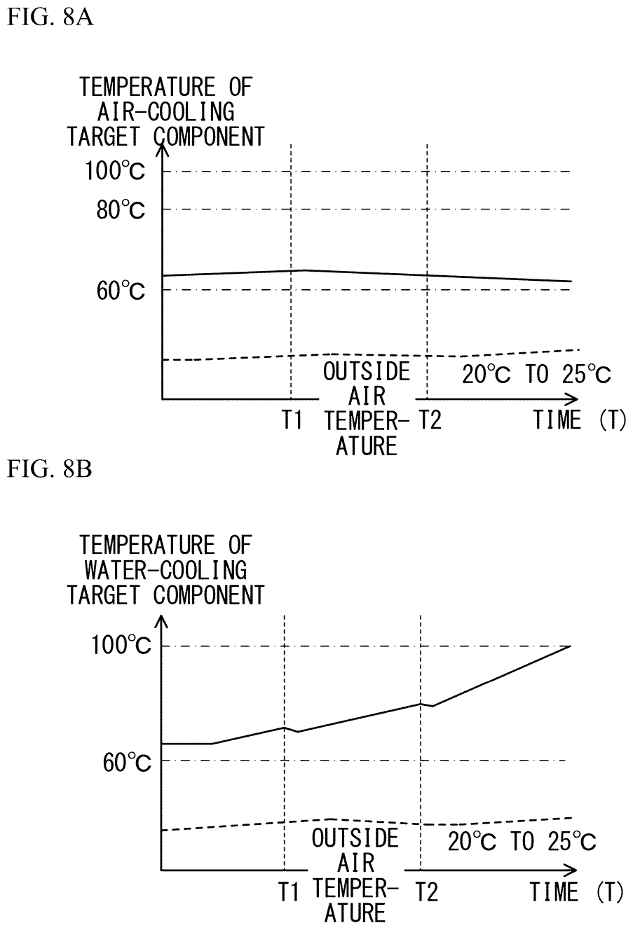

On the other hand, when the temperature monitoring unit 12A determines that the components of which the temperatures are higher than the second threshold temperature are only the water-cooling target components 114 and 115 (step S9: YES), the abnormality determination unit 12B determines whether there is a plurality of water-cooling target components of which the temperatures are higher than the second threshold temperature (step S11). For example, in the case that the components of which the temperatures are higher than the second threshold temperature are only the water-cooling target components 114 and 115, when the outside air temperature above the substrate 111 is within the range of 20° C. to 25° C., the temperatures of the air-cooling target components 112 and 113 fall within the normal temperature range of 60° C. to 80° C. as illustrated in FIG. 8A. On the other hand, as illustrated in FIG. 8B, even when the outside air temperature above the substrate 111 is within the range of 20° C. to 25° C., the temperatures of the water-cooling target components 114 and 115 may exceed the second threshold temperature and become abnormal temperatures.

As described above, when respective temperatures of the air-cooling target components 112 and 113 are normal temperatures and respective temperatures of the water-cooling target components 114 and 115 are abnormal temperatures, the abnormality determination unit 12B can determine that there is a failure in the cooling mechanism 116 or 117 or a decrease in the amount of the coolant supplied to the cooling mechanisms 116 and 117. In this case, the abnormality determination unit 12B determines whether the abnormality is a failure in the cooling mechanism 116 or 117 or a decrease in the amount of the coolant supplied to the cooling mechanisms 116 and 117 based on the temperature relationship between the temperatures of the water-cooling target components 114 and 115.

Here, when there is not a plurality of water-cooling target components of which the temperatures are higher than the second threshold temperature (step S11: NO), the abnormality determination unit 12B determines that there is a failure in the cooling mechanism provided in the water-cooling target component whose temperature has risen (step S12), issues an alarm as necessary, and ends the process. For example, when the temperature of the water-cooling target component 114 is higher than the second threshold temperature, the abnormality determination unit 12B can determine that the temperature of the water-cooling target component 114 is an abnormal temperature. On the other hand, when the temperature of the water-cooling target component 115 is not higher than the second reference temperature, the abnormality determination unit 12B can determine that the temperature of the water-cooling target component 115 is a normal temperature. In such a case, it is difficult to consider that the amount of the coolant commonly flowing through both of the cooling mechanisms 116 and 117 has decreased. Therefore, in this case, the abnormality determination unit 12B determines that there is a failure in the water-cooling target component 114, such as peeling of the cooling mechanism 116 from the water-cooling target component 114 whose temperature has risen.

On the other hand, when there is a plurality of water-cooling target components whose temperatures are higher than the second threshold temperature (step S11: YES), the abnormality determination unit 12B determines that the amount of the coolant has decreased (step S13), issues an alarm as necessary, and ends the process. For example, when the temperatures of the water-cooling target components 114 and 115 are both higher than the second threshold temperature, the abnormality determination unit 12B determines that the temperatures of the water-cooling target components 114 and 115 are abnormal temperatures. In such a case, it may be determined that peeling of the cooling mechanism 117 from the water-cooling target component 114 and peeling of the cooling mechanism 116 from the water-cooling target component 115 have occurred at the same time. However, it is extremely rare for such two events to occur simultaneously. Therefore, in such a case, the abnormality determination unit 12B determines that the abnormality is a decrease in the amount of the coolant commonly supplied to both of the cooling mechanisms 116 and 117. In this manner, the abnormality determination unit 12B can determine whether the amount of the coolant has decreased based on whether there is a plurality of water-cooling target components whose temperatures are higher than the second threshold temperature.

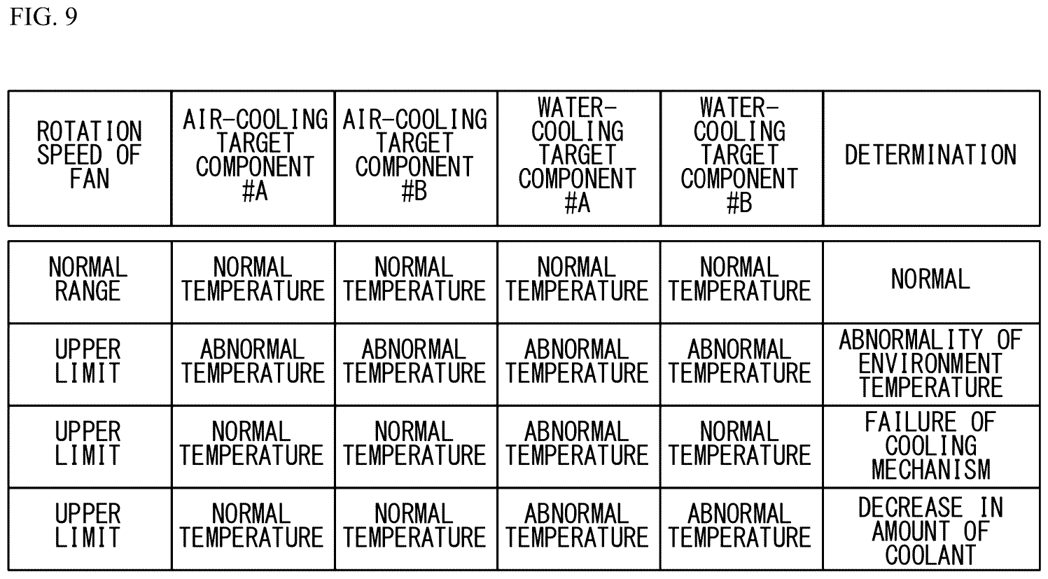

With reference to FIG. 9, the determination criteria of the abnormality determination unit 12B based on the rotation speed of the air-cooling fan 213 and the relationships among respective temperatures of the air-cooling target components 112 and 113, and respective temperatures of the water-cooling target components 114 and 115 will be described. In FIG. 9, an air-cooling target component #A corresponds to the air-cooling target component 112. An air-cooling target component #B corresponds to the air-cooling target component 113. A water-cooling target component #A corresponds to the water-cooling target component 114. The water-cooling target component #B corresponds to the water-cooling target component 115.

First, when the rotation speed of the air-cooling fan 213 is within the normal range, the abnormality determination unit 12B estimates that the respective temperatures of the air-cooling target components 112 and 113 and the water-cooling target components 114 and 115 are all normal temperatures. In this case, the abnormality determination unit 12B determines that the cooling system is operating normally. Next, in the case that the rotation speed of the air-cooling fan 213 is at the upper limit, when the respective temperatures of the air-cooling target components 112 and 113 and the water-cooling target components 114 and 115 are all abnormal temperatures, the abnormality determination unit 12B determines that the environmental temperature is abnormal. For example, the abnormality determination unit 12B determines that the ventilation hole of the rack accommodating the cooling system is blocked.

Next, in the case that the rotation speed of the air-cooling fan 213 has is at the upper limit, when the respective temperatures of the air-cooling target components 112 and 113 and the water-cooling target components 115 are normal temperatures but the temperature of the water-cooling target component 114 is an abnormal temperature, the abnormality determination unit 12B determines that the cooling mechanism 116 has failed. Finally, in the case that the rotation speed of the air-cooling fan 213 is at the upper limit, when the respective temperatures of the air-cooling target components 112 and 113 are normal temperatures, but the respective temperatures of the water-cooling target components 114 and 115 are abnormal temperatures, the abnormality determination unit 12B determines that the coolant supplied to the cooling mechanisms 116 and 117 has decreased.

As described above, in the present embodiment, in the cooling system ST in which air cooling and water cooling are used, the abnormality determination unit 12B can determine an abnormality of the cooling mechanism such as a failure of any one of the cooling mechanisms 116 and 117 and a decrease in the amount of the coolant supplied to the cooling mechanisms 116 and 117.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various change, substitutions, and alterations could be made hereto without departing from the spirit and scope of the invention. For example, the above-described coolant may be cold water or an antifreeze solution.

In the above-described embodiment, the second threshold temperature is used to determine whether the temperature of each of the air-cooling target components 112 and 113 and the water-cooling target components 114 and 115 is a normal temperature or an abnormal temperature. However, this does not intend to suggest any limitation to the temperature determination using the second threshold temperature. For example, the abnormality determination unit 12B may determine whether the temperature of each of the air-cooling target components 112 and 113 and the water-cooling target components 114 and 115 is a normal temperature or an abnormal temperature based on the temperature slope periodically acquired by the temperature monitoring unit 12A. In this case, for example, when the temperature slope is a steep positive slope, the abnormality determination unit 12B may determine that the acquired temperature is an abnormal temperature.

What is claimed is:

1. A monitoring device comprising:
a monitoring unit configured to monitor respective temperatures of an air-cooling target component and water-cooling target components measured by temperature sensors, respectively; and
a determination unit configured to determine an abnormality in any one of cooling mechanisms provided in the water-cooling target components, respectively, based on a temperature relationship among the respective temperatures.

2. The monitoring device according to claim 1, wherein the determination unit determines that a coolant supplied to the cooling mechanisms has decreased when a temperature of the air-cooling target component is normal and temperatures of the water-cooling target components are all abnormal.

3. The monitoring device according to claim 1, wherein when a temperature of the air-cooling target component is normal, temperatures of one or some of the water-cooling target components are normal, and a temperature of a remaining water-cooling target component of the water-cooling target components is abnormal, the determination unit determines that a cooling mechanism provided in the remaining water-cooling target component has failed.

4. The monitoring device according to claim 1, wherein when a temperature of the air-cooling target component is abnormal and temperatures of the water-cooling target components are all abnormal, the determination unit determines that a temperature of a component environment including the air-cooling target component and the water-cooling target components is abnormal.

5. The monitoring device according to claim 1, wherein each of the cooling mechanisms is a plate that is in close contact with a corresponding one of the water-cooling target components and exchanges heat of the corresponding one of the water-cooling target components and heat of a coolant supplied to the cooling mechanisms.

6. The monitoring device according claim 1, wherein the air-cooling target component, the water-cooling target components, the cooling mechanisms, the temperature sensors, a water-cooling pump configured to supply a coolant to the cooling mechanisms, and an air-cooling fan configured to cool the air-cooling target component are provided in a monitored device that is monitored by the monitoring device.

7. The monitoring device according claim 1, wherein the determination unit determines the abnormality based on a rotation speed of an air-cooling fan that cools the air-cooling target component and the temperature relationship among the respective temperatures.

8. The monitoring device according to claim 7, wherein the determination unit estimates that the respective temperatures are normal temperatures when the rotation speed has not reached an upper limit of the rotation speed.

9. A cooling system comprising:
a monitoring device that monitors respective temperatures of an air-cooling target component and water-cooling target components measured by temperature sensors, respectively, and determines an abnormality of any one of cooling mechanisms provided in the water-cooling components, respectively, based on a temperature relationship among the respective temperatures; and
a monitored device that is monitored by the monitoring device and includes the air-cooling target component, the water-cooling target components, the cooling mechanisms, the temperature sensors, a water-cooling pump that supplies a coolant to the cooling mechanism, and an air-cooling fan that cools the air-cooling target component.
